(19) United States
(12) Patent Application Publication
(10) Pub. No.: US 2025/0300002 A1
(43) Pub. Date: Sep. 25, 2025

(54) SUBSTRATE SUPPORT DEVICE AND SEMICONDUCTOR MANUFACTURING APPARATUS INCLUDING THE SAME

(71) Applicant: Samsung Electronics Co., Ltd., Suwon-si (KR)

(72) Inventors: Junho LEE, Pyeongtaek-si (KR); YoungTak SON, Suwon-si (KR); Hansu KIM, Pyeongtaek-si (KR); Jongchan LEE, Pyeongtaek-si (KR); SEOYOUNG MAENG, Suwon-si (KR); HONGSIK PARK, Suwon-si (KR); HAKJUNG KIM, Suwon-si (KR)

(73) Assignees: Samsung Electronics Co., Ltd., Suwon-si (KR); MECARO CO.,LTD., Pyeongtaek-si (KR)

(21) Appl. No.: 18/990,222

(22) Filed: Dec. 20, 2024

(30) Foreign Application Priority Data
Mar. 21, 2024 (KR) 10-2024-0038850

(51) Int. Cl. H01L 21/687; C23C 16/455; C23C 16/458; C23C 16/46

(52) U.S. Cl. CPC H01L 21/68785; C23C 16/45544; C23C 16/45565; C23C 16/4586; C23C 16/46

(57) ABSTRACT

Provided are a substrate support device and a semiconductor manufacturing apparatus including the same. This substrate support device includes a plate having an upper surface configured to support a substrate, and a heater in the plate, in which the heater has a spiral shape that revolves multiple times around a center of the plate with an increasing radius towards an edge of the plate in a plan view. The heater includes a first heater part and a second heater part surrounding the first heater part, in which the first heater part is closer to the center of the plate than the second heater part, and the heater includes at least a first heat line having a helix structure, in which the heat line has a first helix structure with a first pitch in the first heater part and the heat line has a second helix structure with a second pitch in the second heater part, and the second pitch is longer than the first pitch.

### CROSS-REFERENCE TO RELATED APPLICATIONS

This U.S. non-provisional patent application claims priority under 35 U.S.C. § 119 to Korean Patent Application No. 10-2024-0038850, filed on Mar. 21, 2024, the entire contents of which are hereby incorporated by reference.

### BACKGROUND

The present disclosure herein relates to a substrate support device and a semiconductor manufacturing apparatus including the same.

Semiconductor devices may be manufactured through various processes. For example, semiconductor devices may be manufactured through a photolithography process, an etching process, a deposition process, and the like on wafers such as silicon wafers. In such processes, a substrate such as a wafer may be fixed by a substrate support device. The temperature of a substrate may be controlled by a heating means in a substrate support device.

### SUMMARY

The present disclosure provides a substrate support device capable of increasing a temperature of a center portion thereof.

The present disclosure also provides a semiconductor manufacturing apparatus capable of depositing a film with a uniform thickness.

The purposes of the present disclosure are not limited to the above-mentioned purposes, and other purposes not mentioned would be clearly understood by those skilled in the art from the disclosure herein.

An embodiment of the inventive concept provides a substrate support device including: a plate having an upper surface configured to support a substrate; and a heater in the plate, in which the heater has a spiral shape that revolves multiple times around a center of the plate with an increasing radius towards an edge of the plate in a plan view, the heater includes a first heater part and a second heater part surrounding the first heater part, in which the first heater part is closer to the center of the plate than the second heater part. In example embodiments, the heater includes at least a first heat line having a helix structure, the heat line has a first helix structure with a first pitch in the first heater part, and the heat line has a second helix structure, with a second pitch in the second heater part, in which the second pitch is longer than the first pitch. In an embodiment of the inventive concept, a substrate support device includes:

a plate having an upper surface configured to support a substrate; and a heater in the plate, wherein the heater has a spiral shape that revolves multiple times around a center of the plate with an increasing radius towards an edge of the plate in a plan view. In example embodiments, the heater includes a first heater part a second heater part surrounding the first heater part, wherein the first heater part is closer to the center of the plate than the second heater part, the heater includes at least one heat line having a helix structure and includes an alloy of nickel and chromium, and chromium content in the first heater part is higher than chromium content in the second heater part.

In an embodiment of the inventive concept, a semiconductor manufacturing apparatus includes: a chamber defining an outer boundary of a process space; a substrate support device within the chamber and supporting a substrate; and a shower head located on the substrate support device configured to provide a deposition gas to the substrate. According to example embodiments, the substrate support device includes: a plate having an upper surface configured to support a substrate; and a heater in the plate, wherein the heater has a spiral shape that revolves multiple times around a center of the plate with an increasing radius towards an edge of the plate in a plan view, the heater includes a first heater part and a second heater part surrounding the first heater part, the first heater part being closer to the center of the plate than the second heater part. In non-limiting examples, the heater includes at least one heat line having a helix structure, and includes an alloy of nickel and chromium, the heat line has a first thickness in the first heater part, and the heat line has a second thickness in the second heater part, in which the second thickness is larger than the first thickness.

### BRIEF DESCRIPTION OF THE FIGURES

The accompanying drawings are included to provide a further understanding of the inventive concept, and are incorporated in, and constitute a part of, this specification. The drawings illustrate embodiments of the inventive concept and, together with the description, serve to explain principles of the inventive concept. In the drawings:

FIG. 1 is a cross-sectional view of a semiconductor manufacturing apparatus according to embodiments of the inventive concept;

FIG. 2 is a perspective view of a substrate support device according to embodiments of the inventive concept;

FIG. 3 is a cross-sectional view taken along line A-A′ of FIG. 2;

FIG. 4 is a perspective view of an upper surface of a second sub-plate according to embodiments of the inventive concept;

FIG. 5 is a perspective view of a lower surface of the second sub-plate according to embodiments of the inventive concept;

FIG. 6 is a schematic plan view of a plate according to embodiments of the inventive concept;

FIG. 7 is a detailed perspective view of a heater according to embodiments of the inventive concept;

FIG. 8 is a schematic diagram illustrating a shape of a heat line in a heater according to embodiments of the inventive concept;

FIG. 9 is a schematic diagram illustrating a shape of a heat line in a heater according to embodiments of the inventive concept;

FIG. 10 is a schematic diagram illustrating a shape of a heat line in a heater according to embodiments of the inventive concept;

FIG. 11A is a diagram illustrating a result of simulation of temperature distribution on an upper surface of a substrate support device according to embodiments of the inventive concept; and

FIG. 11B is a diagram illustrating a result of simulation of temperature distribution in a cross-section of a substrate support device according to embodiments of the inventive concept.

### DETAILED DESCRIPTION

Hereinafter, embodiments according to the inventive concept will be described in detail with reference to the drawings to describe the inventive concept in more detail.

Herein, the terms indicating order, such as first, second, etc., are used to distinguish elements having the same/similar functions, and the ordinal numbers may be interchanged according to the order in which the terms are mentioned. It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention.

Items described in the singular herein may be provided in plural, as can be seen, for example, in the drawings. Thus, the description of a single item that is provided in plural should be understood to be applicable to the remaining plurality of items unless context indicates otherwise.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. As used herein, the term “and/or” includes any and all combinations of one or more of the associated listed items.

It will be understood that when an element is referred to as being “connected” or “coupled” to or “on” another element, it can be directly connected or coupled to or on the other element or intervening elements may be present.

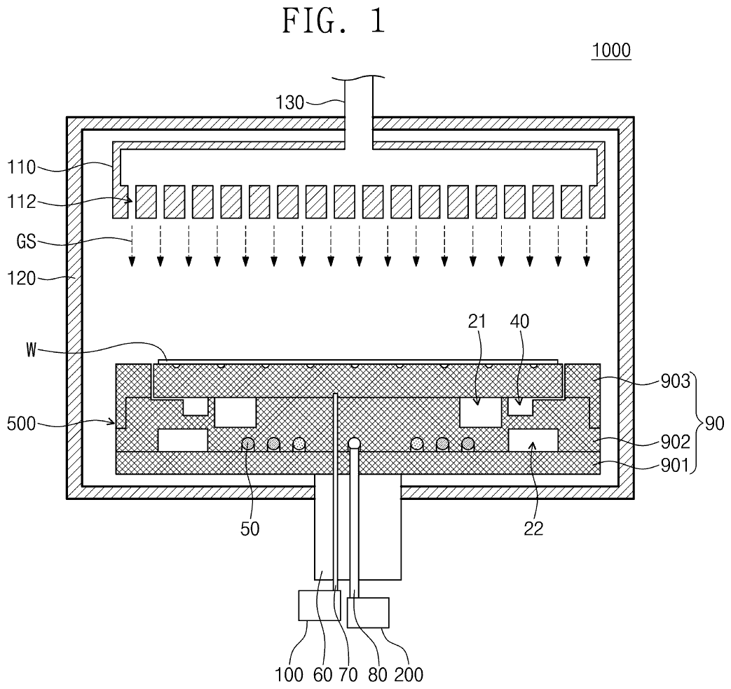

FIG. 1 is a cross-sectional view of a semiconductor manufacturing apparatus according to embodiments of the inventive concept.

Referring to FIG. 1, a semiconductor manufacturing apparatus 1000 may be provided. In an embodiment of the inventive concept, the semiconductor manufacturing apparatus 1000 may also be referred to as a “substrate processing device”. The semiconductor manufacturing apparatus 1000 may be an apparatus for performing a process on a substrate W. The semiconductor manufacturing apparatus 1000 according to the present example may be, for example, a deposition apparatus. In more detail, the semiconductor manufacturing apparatus 1000 may be an apparatus for performing a chemical vapor deposition (CVD), atomic layer deposition (ALD), or low pressure chemical vapor deposition (LPCVD) process on the substrate W. The term “substrate” W used herein may represent a silicon (Si) wafer but is not limited thereto. A substrate may denote a base substrate (e.g., an initial semiconductor substrate forming the base of the wafer in the final wafer product, such as a bulk semiconductor substrate (e.g., formed of crystalline silicon), a silicon on insulator (SOI) substrate, etc.), or a stack structure including such a base substrate, and layers formed on the substrate.

The semiconductor manufacturing apparatus 1000 may include a chamber 120, a substrate support device 500, and a shower head 110.

The chamber 120 may provide a process space therein. The chamber 120 may define the outer boundaries of a process space and separate the process space inside the chamber from an external space outside the chamber. A deposition process may be performed on the substrate in the process space. Pressure in the chamber 120 may be vacuum or low pressure close to vacuum (for example, 10 torr or less).

The substrate support device 500 may be located in the chamber 120. The substrate support device 500 may support and/or fix the substrate W. The substrate support device 500 may control a temperature of the substrate W. For example, the substrate support device 500 may heat the substrate W. In an embodiment of the inventive concept, the substrate support device 500 may enhance center concentration of heat flux generation. Therefore, the substrate support device 500 provided herein may increase a temperature of a center portion of the substrate W and decrease a temperature of a peripheral portion of the substrate W. The substrate support device 500 may include a plate 90 on which the substrate W is placed and a rod 60 disposed under the plate 90. The substrate support device 500 will be described in more detail herein.

The shower head 110 may be spaced apart upwards from the substrate support device 500. In more detail, the shower head 110 may be spaced a certain distance apart upwards from the plate 90. The shower head 110 may provide a plurality of distribution holes 112. The plurality of distribution holes 112 may be arranged spaced apart in a horizontal direction. A process gas GS supplied from a gas supply tube 130 may be sprayed into the process space through the plurality of distribution holes 112 of the shower head 110, and a film of desired material may be deposited on the substrate W due to a chemical reaction between the process gases GS.

The process gas GS may include a source material of a material for forming a film to be deposited on the substrate W. For example, when the film to be deposited is formed of a silicon oxide or silicon nitride, the process gas GS may include monosilane and/or disilane. When the film to be deposited is formed of tungsten, the process gas GS may include WCl₃.

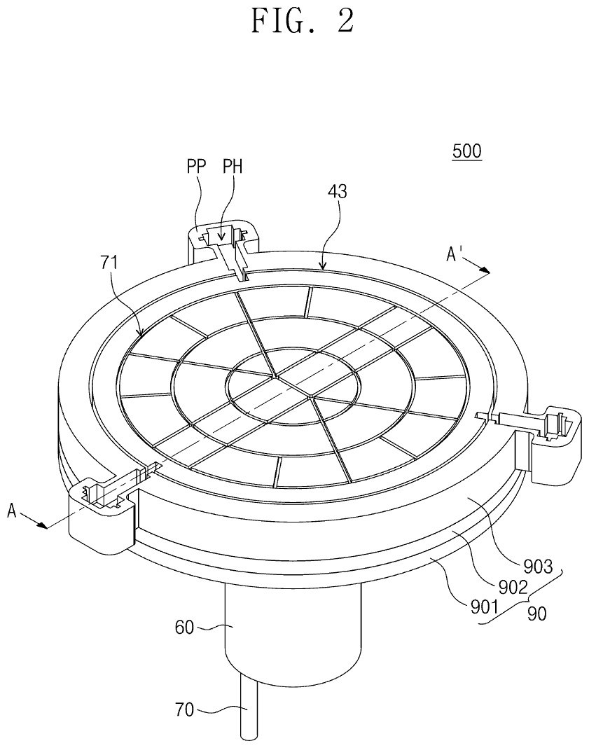

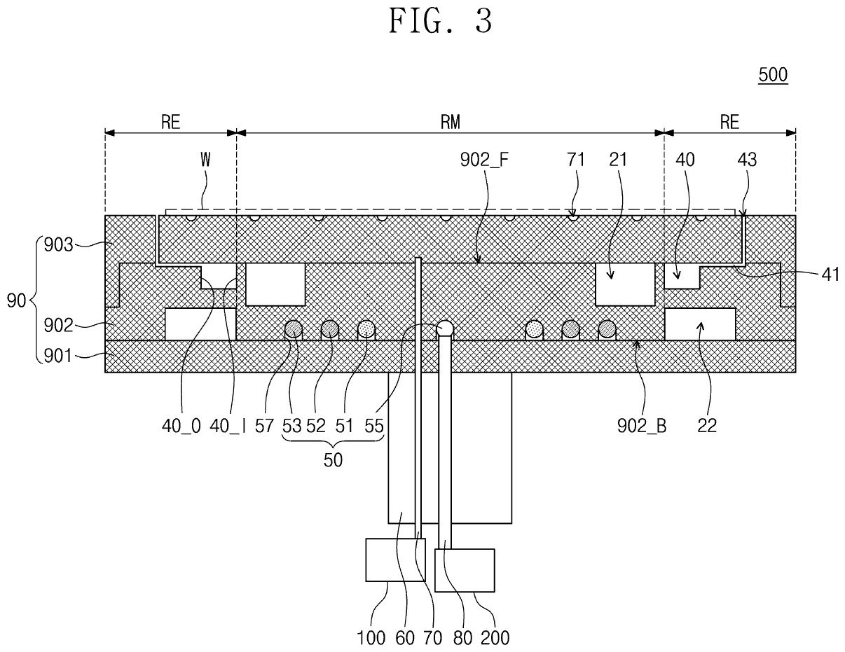

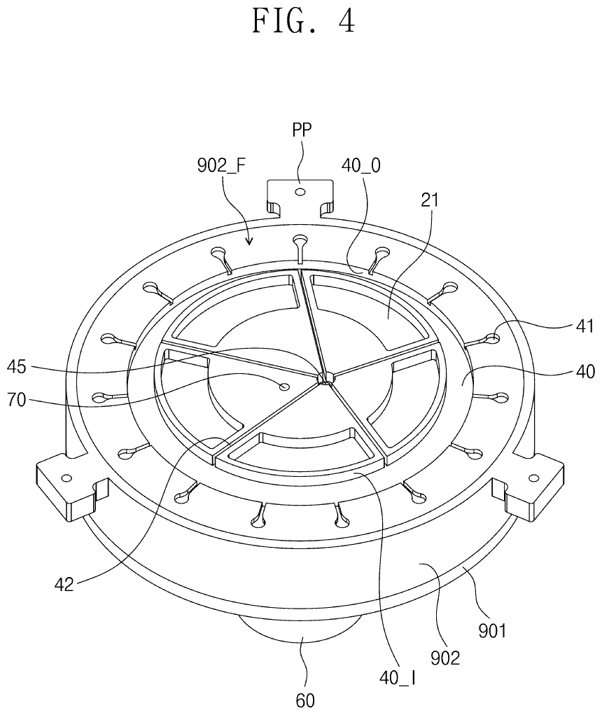

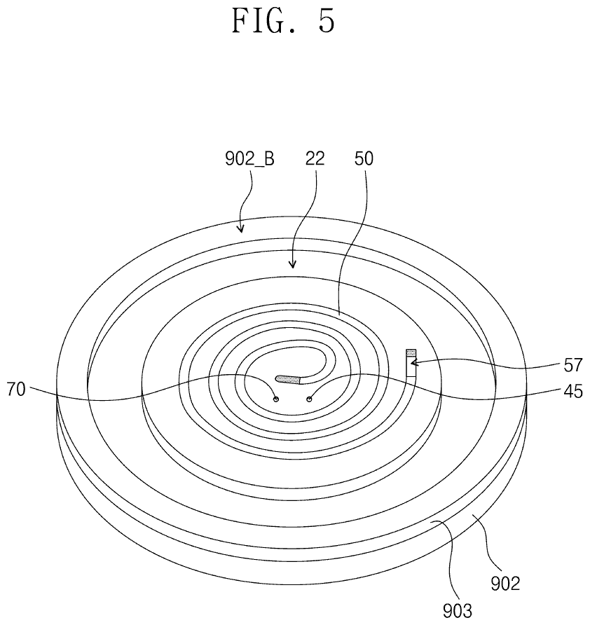

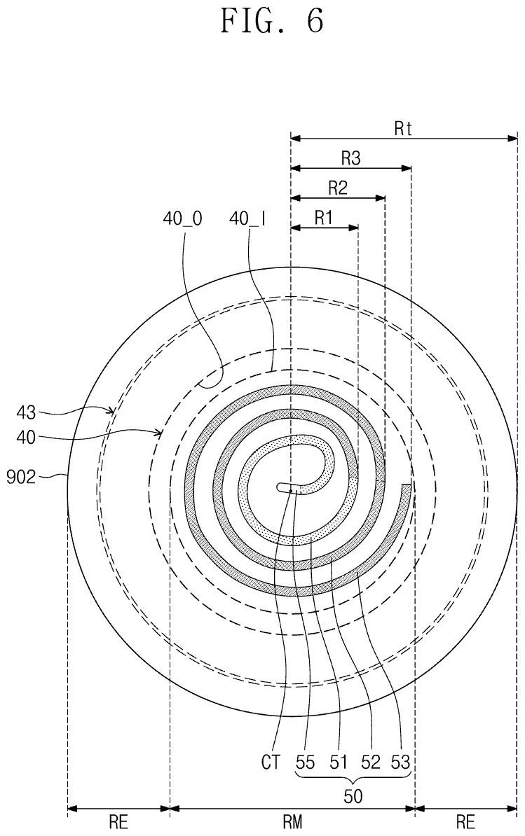

FIG. 2 is a perspective view of a substrate support device according to embodiments of the inventive concept. FIG. 3 is a cross-sectional view taken along line A-A′ of FIG. 2. FIG. 4 is a perspective view of an upper surface of a second sub-plate according to embodiments of the inventive concept. FIG. 5 is a perspective view of a lower surface of the second sub-plate according to embodiments of the inventive concept. FIG. 6 is a schematic plan view of a plate according to embodiments of the inventive concept.

Referring to FIGS. 1 to 6, the plate 90 may have an upper surface configured to place, support and/or fix the substrate W. The plate 90 may include a heater 50 therein. In detail, the plate 90 may include first to third sub-plates 901, 902, and 903 stacked sequentially. The term “stacked sequentially”, relates to the positioning of the sub-plates with respect to one another and is not intended to imply a limitation on the timing of stacking the sub-plates on one another. The first to third sub-plates 901, 902, and 903 may be formed of aluminum, aluminum alloy, or aluminum nitride (AlN) independent of each other. The first to third sub-plates 901, 902, and 903 may be physically coupled to each other. In the present example, the plate 90 is divided into the three sub-plates 901, 902, and 903, but an embodiment of the inventive concept is not limited thereto. For example, the three sub-plates 901, 902, and 903 may be integrally connected to each other so that a single body may constitute the plate 90. In another example, the plate 90 may include two or at least four sub-plates.

Referring to FIGS. 1 and 3, the first sub-plate 901 may be between the second sub-plate 902 and the rod 60. The rod 60 may penetrate a lower portion of the chamber 120. The rod 60 may support the plate 90.

Referring to FIGS. 3 and 6, an edge gas passage 40 and a first cavity region 21 may be arranged in an upper surface 902_F of the second sub-plate 902. The edge gas passage 40 may have a ring shape in a plan view. The edge gas passage 40 may have a first inner surface 40_I that is close to a center of the second sub-plate 902 and a second inner surface 40_O that is close to an edge of the second sub-plate 902.

The second sub-plate 902 may include a center portion RM and a peripheral portion RE surrounding the center portion RM. The center portion RM of the second sub-plate 902 may correspond to a region from a center CT (FIG. 6) of the second sub-plate 902 to the first inner surface 40_I of the edge gas passage 40. The peripheral portion RE of the second sub-plate 902 may correspond to a region from the first inner surface 40_I of the edge gas passage 40 of the second sub-plate 902 to an edge of the second sub-plate 902.

Referring to FIGS. 3 and 4, the edge gas passage 40 may be in the peripheral portion RE of the second sub-plate 902. The first cavity region 21 may be spaced apart from the edge gas passage 40 and located in the center portion RM of the second sub-plate 902 so as to be adjacent to the peripheral portion RE. The first cavity region 21 may be provided in plurality and spaced apart from each other having an arc shape. In another example, the first cavity region 21 may have a single ring shape in a plan view.

The first cavity regions 21 may be spaced the same distance apart from the center CT (FIG. 6) of the second sub-plate 902. Upper ends of the first cavity region 21 and edge gas passage 40 may be defined by a lower surface of the third sub-plate 903. Since the first cavity regions 21 are spaced apart from each other and a bridge portion is formed therebetween, the second sub-plate 902 may be prevented from being warped and may be improved in durability.

Referring to FIGS. 3 and 4, first connection passages 41 and second connection passages 42 connected to the edge gas passage 40 may be formed in the upper surface 902_F of the second sub-plate 902. A width of the edge gas passage 40 may be larger than a width of each of the first connection passages 41 and the second connection passages 42.

The first connection passages 41 may be radially arranged extending from the second inner surface 40_O of the edge gas passage 40. The second connection passages 42 may extend from the first inner surface 40_I of the edge gas passage 40 to the center portion RM of the second sub-plate 902. The second connection passages 42 may be provided in plurality and connected to each other. The second connection passages 42 may have different lengths in a plan view. An edge gas supply tube 45 may be formed at a point at which the second connection passages 42 meet in the second sub-plate 902. The edge gas supply tube 45 may penetrate the first sub-plate 901 and the second sub-plate 902. The edge gas supply tube 45 may be in the rod 60 and connected to an external edge gas supply device.

Referring to FIGS. 2 and 3, an edge gas discharge groove 43 is formed in an upper surface of the third plate 903. The edge gas discharge groove 43 may have a ring shape in a plan view. The edge gas discharge groove 43 may penetrate the third plate 903 and may be connected to the first connection passages 41. An inert gas such as argon may be supplied to an edge of the substrate W through the edge gas supply tube 45, the second connection passages 42, the edge gas passage 40, and the edge gas discharge groove 43. The inert gas such as argon supplied to the edge of the substrate W through the edge gas discharge groove 43 may serve to prevent a film from being deposited thick at the edge of the substrate W.

Referring to FIGS. 2 and 3, vacuum grooves 71 are further formed in the upper surface of the third plate 903. In a plan view, the vacuum grooves 71 may be arranged inside the edge gas discharge groove 43 having a ring shape. The vacuum grooves 71 may have a mesh shape including a plurality of rings and radial lines connecting the rings as illustrated in FIG. 2. The vacuum grooves 71 may be connected to a vacuum tube 70 penetrating the rod 60. The vacuum tube 70 may be connected to a vacuum pump 100. Vacuum pressure may be applied to a lower surface of the substrate W by the vacuum pump 100, the vacuum tube 70, and the vacuum grooves 71, thus fixing the substrate W.

Protrusions PP protruding outwards may be formed on edges of the second sub-plate 902 and the third sub-plate 903. The protrusions PP may include holes PH and may be used to fix an edge ring (not shown) covering an edge of the plate 90.

Referring to FIGS. 3 and 5, a heater groove 57 and a second cavity region 22 are formed in a lower surface 902_B of the second sub-plate 902. The second cavity region 22 may have a ring shape in a plan view and surround the heater groove 57. In another example, the second cavity region 22 may be provided in plurality and spaced apart from each other having an arc shape. The second cavity region 22 may be in the peripheral portion RE of the second sub-plate 902. The second cavity region 22 may be spaced apart from and vertically overlap the edge gas passage 40. A lower end of the second cavity region 22 may be defined by an upper surface of the first sub-plate 901.

The heater groove 57 may be in the center portion RM of the second sub-plate 902. In a plan view, the heater groove 57 may have a spiral shape that revolves multiple times around the center CT of the plate 90 with an increasing radius towards an edge of the plate 90. As used herein, the term “spiral” when referring to a heater and a heater groove, does not need to have a uniform distance between the revolutions. Spiral as used herein may include any shape in which the spiral has a center point and revolutions around the center point with increasing diameter. The heater 50 is in the heater groove 57. The heater 50 may be in the center portion RM of the second sub-plate 902. The heater 50 is spaced apart from and does not vertically overlap the edge gas passage 40. A portion of the heater 50 may vertically overlap the first cavity region 21.

Referring to FIG. 6, in a plan view, the heater 50 may have a spiral shape that revolves multiple times around the center CT of the plate 90 with an increasing radius towards an edge of the plate 90. The heater 50 may include a connection part 55 and first to third heater parts 51, 52, and 53. The connection part 55 and the first to third heater parts 51, 52, and 53 may be continuously connected to each other.

The connection part 55 may overlap the center CT of the plate 90 and, in a plan view, may have a linear shape partially. A heater connection line 80 may penetrate the first sub-plate 901 and the rod 60 and connect the connection part 55 of the heater 50 to a heater power adjustment device 200.

The first heater part 51 may correspond to a part of the heater 50, which is located within a first radius R1 from the center CT of the plate 90 and wraps around the center CT of the plate 90 by one turn. The second heater part 52 may correspond to a part of the heater 50 which is located within a range from the first radius R1 to a second radius R2 and wraps around the center CT of the plate 90 by two turns. The second radius R2 is larger than the first radius R1. The third heater part 53 may correspond to a part of the heater 50 which is located within a range from the second radius R2 to a third radius R3 and wraps around the center CT of the plate 90 by three turns. The third radius R3 is larger than the second radius R2. An outermost point of the third heater part 53 may be located within the third radius R3 from the center CT of the plate 90 and within a range of about ½ to about ⅔ of a total radius Rt of the plate 90.

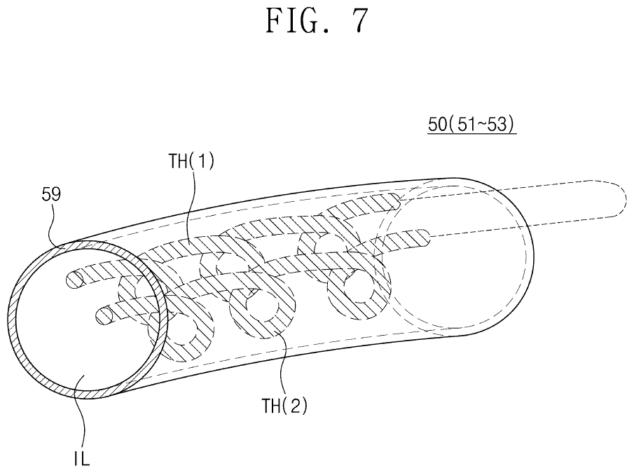

FIG. 7 is a detailed perspective view of the heater 50 according to embodiments of the inventive concept.

Referring to FIG. 7, the heater 50 according to an embodiment of the inventive concept may have a multi-power density or heat density structure. The heater 50 may be of a cartridge type or sheath type. According to an example, the heater 50 may include a pipe 59, at least one heat line TH may be within the pipe 59. The heater 50 may further include an insulator IL filling a space between the at least one heat line TH and an inner wall of the pipe 59. The heat line TH may be referred to as a coil. In the heater 50 according to an embodiment of the inventive concept, a total resistance of the heat line TH is increased at a portion that is close to the center CT and reduced at a portion that is far away from the center CT so that center concentration may be enhanced during heat flux generation.

The pipe 59 may include, for example, at least one material selected from the group consisting of stainless use steel (SUS), aluminum, incoloy, and inconel, and may be particularly composed of INCOLOY840. The insulator IL may include, for example, at least one material selected from the group consisting of magnesium oxide (MgO) and boron nitride (BN), and in particular, may include magnesium oxide. The pipe 59 may have a diameter of, for example, about 6 mm to about 9 mm. As described above, since a bend radius limit of the pipe 59 is reduced by reducing the diameter of the pipe 59, symmetry of the heat line TH or the heater 50 may be ensured, and a diameter of the heater 50 may be reduced for each turn of the heater 50. Accordingly, heat flux density may be increased by increasing density of the heater 50 in the center portion RM.

The heat line TH may be entirely connected as a single continuous piece over the connection part 55 and the first to third heater parts 51, 52, and 53. The heat line TH may include a conductive material and may include, for example, metal such as copper, nickel, or chromium. According to an example, the heat line TH may include an alloy of nickel and chromium (Ni_{X}Cr_{Y}). The heat line TH may be provided in plurality in the pipe 59. According to an example, the heat lines TH may include a first heat line TH(1) and a second heat line TH(2) spaced apart from each other. Ends of the first heat line TH(1) and the second heat line TH(2) may be connected to each other at an outermost point of the third heater part 53.

The connection part 55 may emit no heat or a small amount of heat. The heat lines TH may have a straight line shape in the connection part 55.

The heat lines TH may emit heat in the first to third heater parts 51, 52, and 53. The heat lines TH may have a helix structure in the first to third heater parts 51, 52, and 53. The term “helix” is intended to mean a single three-dimensional structure that curves. As the term is used herein, a helix does not need to have a uniform spiral shape. In an embodiment of the inventive concept, a heat temperature of the first heater part 51 may be higher than heat temperatures of the second and third heater parts 52 and 53. A heat generation amount of the first heater part 51 may be larger than heat generation amounts of the second and third heater parts 52 and 53. To this end, an electrical resistance of the heat lines TH in the first heater part 51 may be higher than the electrical resistances of the heat lines TH in the second and third heater parts 52 and 53.

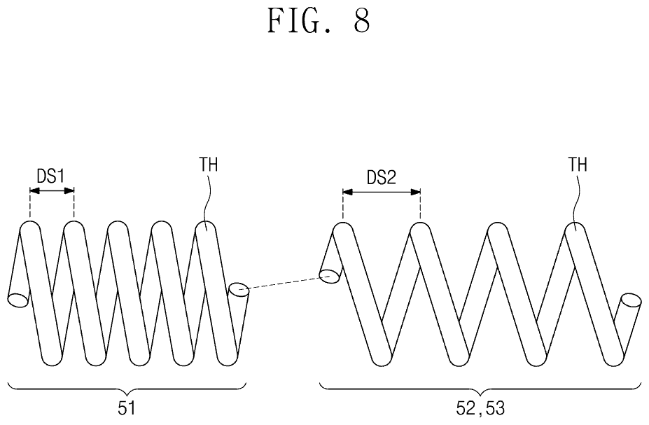

FIG. 8 is a schematic diagram illustrating a shape of a heat line in a heater according to embodiments of the inventive concept.

Referring to FIG. 8, density of the heat line(s) TH in the first heater part 51 may be higher than the density of the heat line(s) TH in the second and third heater parts 52 and 53. In detail, the heat lines TH may have a helix structure with a first pitch DS1 (or first distance) in the first heater part 51. For example, a distance between threads of the heat lines TH may be the first pitch DS1 in the first heater part 51. The heat lines TH may have a helix structure with a second pitch DS2 (or second distance) longer than the first pitch DS1 in the second and third heater parts 52 and 53. For example, the distance between the threads of the heat lines TH may be the second pitch DS2 longer than the first pitch DS1 in the second and third heater parts 52 and 53. Therefore, the heat temperature of the first heater part 51 may be higher than the heat temperatures of the second and third heater parts 52 and 53. As used herein, the “pitch” of a helix is the height of one complete helix turn, measured parallel to the axis of the helix.

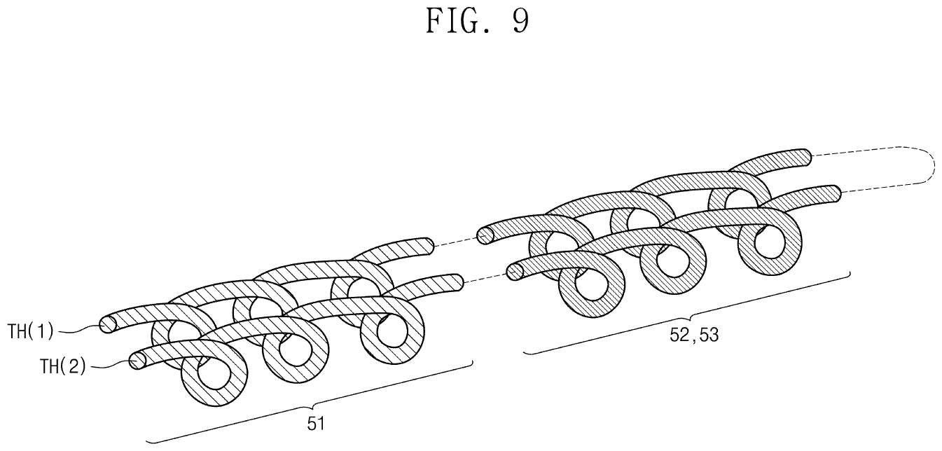

FIG. 9 is a schematic diagram illustrating a shape of a heat line in a heater according to embodiments of the inventive concept.

Referring to FIG. 9, a material of the heat line(s) TH in the first heater part 51 may be different from a material of the heat line(s) TH in the second and third heater parts 52 and 53. As a specific example, a composition of nickel and chromium of the heat lines TH in the first heater part 51 may be different from the composition of nickel and chromium of the heat lines TH in the second and third heater parts 52 and 53. Nickel may have a lower electrical resistance than chromium. For example, chromium content in the heat lines TH in the first heater part 51 may be higher than chromium content in the heat lines TH in the second and third heater parts 52 and 53. Accordingly, the electrical resistance of the heat lines TH in the first heater part 51 may be higher than the electrical resistance of the heat lines TH in the second and third heater parts 52 and 53. As a result, the heat temperature of the first heater part 51 may be higher than the heat temperatures of the second and third heater parts 52 and 53. The composition of nickel and chromium may gradually and continuously change in a vicinity of boundaries between the first to third heater parts 51, 52, and 53.

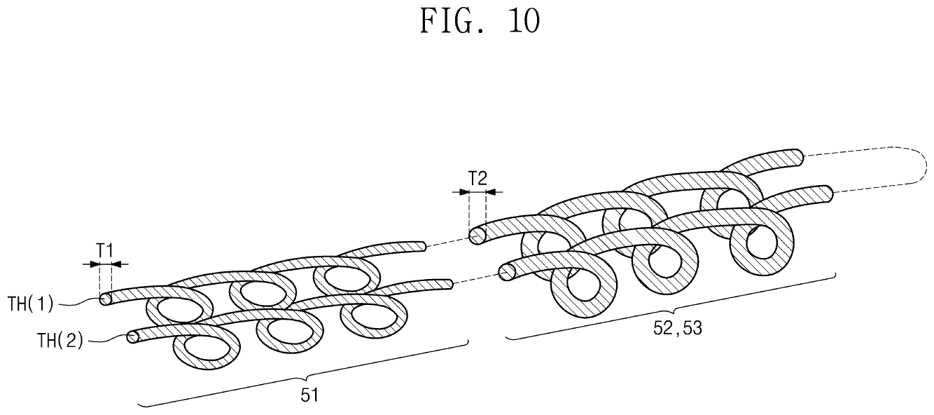

FIG. 10 is a schematic diagram illustrating a non-limiting shape of a heat line in a heater according to embodiments of the inventive concept.

Referring to FIG. 10, the heat lines TH may have a first thickness T1 (e.g., diameter) in the first heater part 51. The heat lines TH may have a second thickness T2 (e.g., diameter), which is different from the first thickness T1 in the second and third heater parts 52 and 53. For example, the second thickness T2 may be larger than the first thickness T1. Accordingly, the electrical resistance of the heat lines TH in the first heater part 51 may be higher than the electrical resistance of the heat lines TH in the second and third heater parts 52 and 53. As a result, the heat temperature of the first heater part 51 may be higher than the heat temperatures of the second and third heater parts 52 and 53. The thickness of the heat lines TH may gradually and continuously change in a vicinity of boundaries between the first to third heater parts 51, 52, and 53.

In the substrate support device 500 according to an embodiment of the inventive concept, the heater 50 is located in the center portion RM of the plate 90 and has an above-mentioned special structure, and thus may effectively heat the center portion RM of the plate 90. Furthermore, because the connection part 55 and first to third heater parts 51, 52, and 53 of the heater 50 are integrally connected to each other and the heat line TH is connected as one piece, the temperature may be controlled by the single heater power adjustment device 200. Therefore, a manufacturing cost may be reduced.

The heater 50 is located inside the edge gas passage 40 in the substrate support device 500 according to an embodiment of the inventive concept. That is, the edge gas passage 40 is located in the peripheral portion RE of the plate 90. Furthermore, the first and second cavity regions 21 and 22 are also arranged in proximity to the peripheral portion RE of the plate 90. The edge gas passage 40 and the first and second cavity regions 21 and 22 may act as an air pocket or air gap so as to delay transfer of heat generated in the heater 50 to the peripheral portion RE of the plate 90. Accordingly, a temperature of the center portion RM of the plate 90 may be further increased than that of the peripheral portion RE of the plate 90.

As the temperature of the substrate W increases, a thickness of a film deposited on the substrate W may increase. A film may be deposited relatively thin on a center portion of the substrate W due to influence of the shower head 110 or the like. However, since the substrate support device 500 has an above-mentioned special structure in an embodiment of the inventive concept, the center portion of the substrate W may be well heated and the temperature of the center portion of the substrate W may be increased. Therefore, the thickness of a film deposited on the center portion of the substrate W may be increased. Accordingly, the film may be deposited to a uniform thickness on the substrate W.

It should be understood that the embodiments of FIGS. 8 to 10 may be combined with each other.

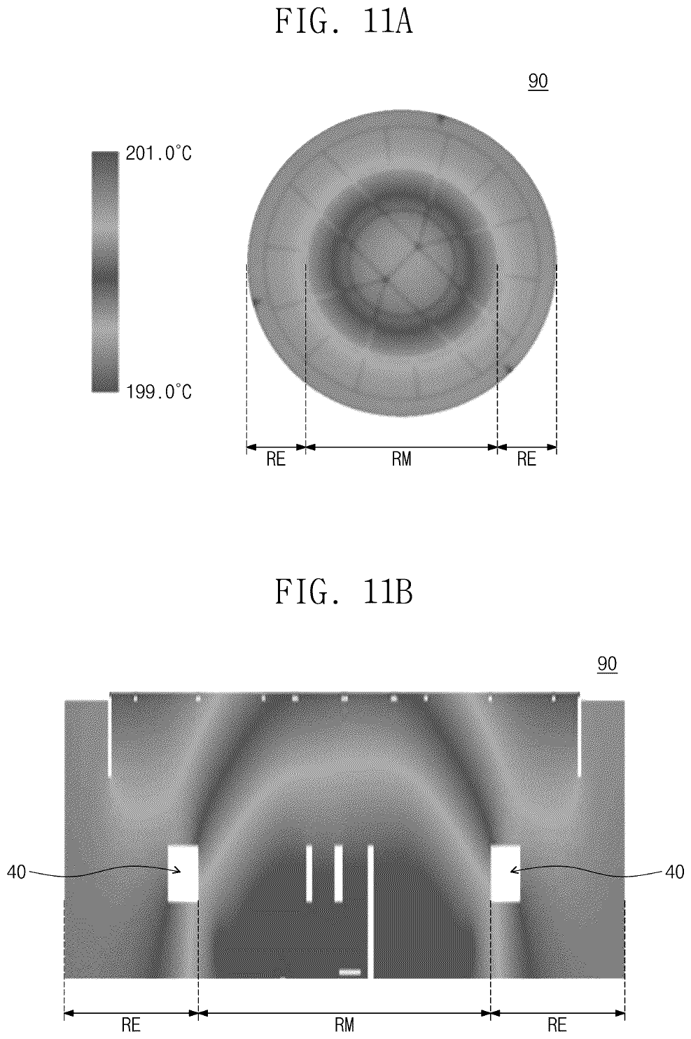

FIG. 11A is a diagram illustrating a result of simulation of temperature distribution on an upper surface of a substrate support device according to embodiments of the inventive concept. FIG. 11B is a diagram illustrating a result of simulation of temperature distribution in a cross-section of a substrate support device according to embodiments of the inventive concept. Referring to FIGS. 11A and 11B, it may be understood that the temperature of the plate 90 is about 200° C., and the temperature of the center portion RM of the plate 90 is about 1-2° C. higher than that of the peripheral portion RE. In example embodiments the temperature of the plate 90 is about 199-201° C. To clarify how the temperature corresponds to the diagrams, the outer portion of FIG. 11A corresponds to approximately 199.5° C., with the temperature rising approaching the center of the plate. The darker portion of the plate corresponds to about 200° C. with the center approaching 200.5° C. In FIG. 11B, the bottom center portion RM of the Figure corresponds to a temperature of about 201° C., with the temperature dropping higher up in the figure to a temperature of 200° C. in the top of the center portion RM. In the peripheral portions RE, the bottom of FIG. 11B has a temperature of about 200° C., with the temperature dropping toward the top of the figure and closer to the center RM, to a temperature of 199° C.

In another example of the inventive concept, the second and third heater parts 52 and 53 may have different electrical resistances. For example, the heat temperature of the second heater part 52 may be lower than the heat temperature of the first heater part 51 but may be higher than the heat temperature of the third heater part 53. The electrical resistance of the heat line TH of the second heater part 52 may be lower than the electrical resistance of the heat line TH of the first heater part 51 but may be higher than the electrical resistance of the heat line TH of the third heater part 53. A second pitch of the heat line TH of the second heater part 52 may be longer than a first pitch of the heat line TH of the first heater part 51 but may be shorter than the pitch of the heat line TH of the third heater part 53. The chromium content in the heat line TH of the second heater part 52 may be lower than the chromium content in the heat line TH of the first heater part 51 but may be higher than the chromium content in the heat line TH of the third heater part 53. Alternatively, the thickness of the heat line TH of the second heater part 52 may be larger than the thickness of the heat line TH of the first heater part 51 but may be smaller than the thickness of the heat line TH of the third heater part 53.

In an embodiment of the inventive concept, the heater 50 has the first to third heater parts 51, 52, and 53, but is not limited thereto and may have two heater parts or at least four heater parts having different heat temperatures.

In an embodiment of the inventive concept, the heater 50 is in the center portion RM of the plate 90 and the edge gas passage 40 and the first and second cavity regions 21 and 22 are arranged in proximity to the peripheral portion RE of the plate 90 so as to increase the temperature of the center portion RM of the plate 90. However, according to another example, in order to increase the temperature of the peripheral portion RE of the plate 90, the heater 50 may be in the peripheral portion RE of the plate 90 and the edge gas passage 40 and the first and second cavity regions 21 and 22 may be located in the center portion RM of the plate 90.

In an embodiment of the inventive concept, the semiconductor manufacturing apparatus 1000 of FIG. 1 is described as a deposition apparatus, but may be used as a dry etching apparatus. In this case, an etchant may be supplied from the shower head 110, and a surface of the substrate W may be etched or a film formed on the substrate W may be etched. Here, the temperature of the substrate support device 500 may be adjusted as described above so that an etching process may be uniformly performed regardless of a location of a target to be etched.

The substrate support device according to an embodiment of the inventive concept may effectively heat a center portion of a plate because a heater is located in the center portion of the plate. Because a heat temperature increases as the heater is closer to the center, the center portion of the plate may be effectively heated. Because an edge gas passage and a cavity region are located in proximity to a peripheral portion of the plate, loss of heat from the center portion of the plate to the peripheral portion may be reduced. Furthermore, temperatures may be adjusted by a single heater power adjustment device since a heater is formed as a single integrated piece, and thus cost may be reduced. Therefore, process characteristics of a substrate may be improved.

A semiconductor manufacturing apparatus according to an embodiment of the inventive concept includes the above-mentioned substrate support device, and thus may deposit a film with a uniform thickness regardless of a location.

Although embodiments of the present invention have been described with reference to the accompanying drawings, those of ordinary skill in the art could easily understood that the present invention can be carried out in other specific forms without changing the technical concept or essential features. Therefore, the above embodiments should be considered illustrative and should not be construed as limiting.

What is claimed is:

1. A substrate support device comprising:
a plate having an upper surface configured to support a substrate; and
a heater in the plate,
wherein the heater has a spiral shape that revolves multiple times around a center of the plate with an increasing radius towards an edge of the plate in a plan view,
the heater includes a first heater part and a second heater part surrounding the first heater part, wherein the first heater part is closer to the center of the plate than the second heater part,
the heater includes at least one heat line having a helix structure,
the heat line has a first helix structure with a first pitch in the first heater part, and
the heat line has a second helix structure with a second pitch in the second heater part, wherein the second pitch is longer than the first pitch.

2. The substrate support device of claim 1, wherein the heater includes:
a pipe, wherein the heat line is within the pipe; and
an insulator between an inner wall of the pipe and the heat line.

3. The substrate support device of claim 2,
wherein the pipe comprises at least one material selected from the group consisting of stainless use steel (SUS), aluminum, incoloy, and inconel, and
wherein the insulator comprises at least one material selected from the group consisting of magnesium oxide (MgO) and boron nitride (BN).

4. The substrate support device of claim 1,
wherein the heat line comprises an alloy of nickel and chromium, and
wherein a composition of nickel and chromium in the first heater part of the heat line is different from a composition of nickel and chromium in the second heater part of the heat line.

5. The substrate support device of claim 1,
wherein the heat line has a first thickness in the first heater part, and
the heat line has a second thickness in the second heater part, wherein the second thickness is different from the first thickness.

6. The substrate support device of claim 1,
wherein the plate includes a center portion and a peripheral portion surrounding the center portion in a plan view,
the heater is in the center portion, and
the first heater part is connected to the second heater part.

7. The substrate support device of claim 1,
wherein the plate includes a first sub-plate, a second sub-plate, and a third sub-plate that are sequentially stacked,
a lower surface of the second sub-plate has a first groove, wherein the heater is in the first groove,
an upper surface of the second sub-plate includes an edge gas passage configured to supply an inert gas to an edge of the substrate, and
the edge gas passage is closer to the edge of the plate than to an outermost periphery of the heater.

8. The substrate support device of claim 7, wherein the edge gas passage does not vertically overlap the heater.

9. The substrate support device of claim 7, wherein the lower surface of the second sub-plate includes at least one first cavity region vertically overlapping the edge gas passage.

10. The substrate support device of claim 9, wherein the upper surface of the second sub-plate includes at least one second cavity region spaced apart from the edge gas passage and vertically overlapping the second heater part.

11. The substrate support device of claim 7, wherein the plate includes:
an upper surface of the third sub-plate having a vacuum groove capable of providing a vacuum force capable of suctioning the substrate; and
an edge gas discharge groove connected to the edge gas passage, wherein the edge gas discharge groove capable of discharging the inert gas.

12. A substrate support device comprising:
a plate having an upper surface configured to support a substrate; and
a heater in the plate,
wherein the heater has a spiral shape that revolves multiple times around a center of the plate with an increasing radius towards an edge of the plate in a plan view,
the heater includes a first heater part and a second heater part surrounding the first heater part, wherein the first heater part is closer to the center of the plate than the second heater part,
the heater includes at least one heat line having a helix structure and comprises an alloy of nickel and chromium, and
a chromium content in the first heater part is higher than a chromium content in the second heater part.

13. The substrate support device of claim 12,
wherein the heat line has a first helix structure with a first pitch in the first heater part, and
the heat line has a second helix structure with a second pitch in the second heater part, wherein the second pitch is longer than the first pitch.

14. The substrate support device of claim 12, wherein the heater includes:
a pipe, wherein the heat line is within the pipe; and
an insulator between an inner wall of the pipe and the heat line.

15. The substrate support device of claim 12,
wherein the heat line has a first thickness in the first heater part, and
the heat line has a second thickness in the second heater part, wherein the second thickness is different from the first thickness.

16. The substrate support device of claim 12,
wherein the plate includes a first sub-plate, a second sub-plate, and a third sub-plate that are sequentially stacked,
a lower surface of the second sub-plate has a first groove, wherein the heater is in the first groove,
an upper surface of the second sub-plate includes an edge gas passage configured to supply an inert gas to an edge of the substrate, and
the edge gas passage is closer to the edge of the plate than to an outermost periphery of the heater.

17. The substrate support device of claim 16, wherein the lower surface of the second sub-plate includes at least one first cavity region vertically overlapping the edge gas passage.

18. A semiconductor manufacturing apparatus comprising:
a chamber defining an outer boundary of a process space;
a substrate support device within the chamber and supporting a substrate; and
a shower head located on the substrate support device configured to provide a deposition gas to the substrate,
wherein the substrate support device includes:
a plate having an upper surface configured to support a substrate; and
a heater in the plate,
wherein the heater has a spiral shape that revolves multiple times around a center of the plate with an increasing radius towards an edge of the plate in a plan view,
the heater includes a first heater part and a second heater part surrounding the first heater part, wherein the first heater part is closer to the center of the plate than the second heater part,
the heater includes at least one heat line having a helix structure and comprises an alloy of nickel and chromium,
the heat line has a first thickness in the first heater part, and
the heat line has a second thickness in the second heater part, in which the second thickness is larger than the first thickness.

19. The semiconductor manufacturing apparatus of claim 18,
wherein the plate includes a first sub-plate, a second sub-plate, and a third sub-plate that are sequentially stacked,
a lower surface of the second sub-plate has a first groove, wherein the heater is in the first groove,
an upper surface of the second sub-plate includes an edge gas passage configured to supply an inert gas to an edge of the substrate, and
the edge gas passage is closer to the edge of the plate than to an outermost periphery of the heater.

20. The semiconductor manufacturing apparatus of claim 19, wherein the lower surface of the second sub-plate includes at least one first cavity region vertically overlapping the edge gas passage.
